(19) United States
(12) Patent Application Publication
(10) Pub. No.: US 2026/0156897 A1
(43) Pub. Date: Jun. 4, 2026

(54) Thin Film Transistor, Manufacturing Method of Thin Film Transistor and Display Apparatus Comprising the Same

(71) Applicant: LG Display Co., Ltd., Seoul (KR)

(72) Inventors: Younghyun Ko, Paju-si (KR); Jaeman Jang, Paju-si (KR); Sungju Choi, Paju-si (KR); Jihee Ryu, Paju-si (KR)

(21) Appl. No.: 19/193,220

(22) Filed: Apr. 29, 2025

(30) Foreign Application Priority Data
Dec. 3, 2024 (KR) 10-2024-0177222

(51) Int. Cl. H10D 64/23; H10D 30/01; H10D 30/67

(52) U.S. Cl. CPC H10D 64/258; H10D 30/0314; H10D 30/6731

(57) ABSTRACT

A thin film transistor comprises: an active layer; a gate insulating film on the active layer, a gate electrode at least partially overlapping the active layer, and a source electrode and a drain electrode connected to the active layer and spaced apart from each other, wherein the drain electrode and the gate electrode are formed integrally, the gate insulating film includes a first gate insulating film overlapping the gate electrode, and the drain electrode contacts the active layer along a side surface of the first gate insulating film.

### CROSS-REFERENCE TO RELATED APPLICATION

This application claims the benefit of priority of Republic of Korea Patent Application No. 10-2024-0177222 filed on Dec. 3, 2024, which is hereby incorporated by reference in its entirety.

### BACKGROUND

### Field of Technology

The present disclosure relates to a thin film transistor, a method for manufacturing a thin film transistor, and a display device including a thin film transistor.

### Discussion of the Related Art

Transistors are widely used as switching devices or driving devices in the field of electronic devices. In particular, thin film transistors are widely used as switching devices in display devices such as liquid crystal display devices or organic light emitting devices because they can be manufactured on glass or plastic substrates.

To ensure driving stability, a diode thin film transistor is used, which allows current to flow in only one direction.

These diode thin film transistors have the advantage of maintaining a stable threshold voltage of the pixel because current flows in only one direction.

Recently, research has been continuously conducted to minimize the area of diode thin film transistors.

### SUMMARY

One embodiment of the present invention is to provide a thin film transistor with a minimized area by forming a drain electrode and a gate electrode integrally.

Another embodiment of the present invention is to provide a thin film transistor in which the depth of penetration of the conductorization is controlled by having a plurality of contact regions between the drain electrode and the active layer.

In accordance with an embodiment of the present disclosure, the above and other objects can be accomplished by the provision of a thin film transistor comprising: an active layer; a gate insulating film on the active layer; a gate electrode at least partially overlapping the active layer; and a source electrode and a drain electrode connected to the active layer and spaced apart from each other, wherein the drain electrode and the gate electrode are formed integrally, the gate insulating film includes a first gate insulating film overlapping the gate electrode, and the drain electrode contacts the active layer along a side surface of the first gate insulating film.

The drain electrode and the gate electrode may be formed integrally within a region overlapping the active layer in a plane.

The drain electrode, the gate electrode and the source electrode can be disposed on the same layer.

The active layer includes a channel portion overlapping the gate electrode; a first conductor portion disposed on one side of the channel portion; a second conductor portion disposed on the other side of the channel portion; and a semiconductor portion overlapping the source electrode, wherein the second conductor portion is disposed between the channel portion and the semiconductor portion, at least a portion of the first conductor portion is in contact with the drain electrode, the gate insulating film further includes a second gate insulating film overlapping the source electrode, the source electrode is in contact with the active layer along a side surface of the second gate insulating film, and the first gate insulating film and the second gate insulating film can be disposed on the same layer and spaced apart from each other.

In a plane, when the drain electrode contacts the active layer in a first contact region, the source electrode contacts the active layer in a second contact region, and the direction connecting the source electrode and the drain electrode with the shortest distance is referred to as a first direction, and a direction perpendicular to the first direction is referred to as a second direction, the first contact region and the second contact region can be disposed to extend along the second direction, respectively.

The first contact region and the second contact region are spaced apart from each other, the first contact region overlaps the first conductor portion, and the second contact region can overlap the second conductor portion.

In a plane, the first contact area and the second contact area can be spaced apart from the end of the active layer with respect to the second direction.

At least one of the first contact area and the second contact area may overlap an end of the active layer in the second direction in a plane.

The first contact region includes a plurality of first sub-contact regions, and the first sub-contact regions can be disposed spaced apart from each other based on the second direction in a plane.

The first gate insulating film may be disposed between the plurality of first sub-contact regions in a plane.

The second contact region includes a plurality of second sub-contact regions spaced apart from each other, and the second sub-contact regions can be disposed spaced apart from each other based on the second direction in a plane.

The gate insulating film further includes a second gate insulating film overlapping the source electrode, and the second gate insulating film can be disposed between the plurality of second sub-contact regions in a plane.

Another embodiment of the present disclosure provides a method for manufacturing a thin film transistor, comprising: forming an active layer; forming a gate insulating material layer on the active layer; etching the gate insulating material layer to form a first open area and a second open area; forming a drain electrode, a gate electrode, and a source electrode on the gate insulating material layer; and etching the gate insulating material layer using the drain electrode, the gate electrode, and the source electrode as a mask to form a gate insulating film, wherein the drain electrode is in contact with the active layer within the first open area, the source electrode is in contact with the active layer within the second open area, and the drain electrode and the gate electrode are formed integrally.

Another embodiment of the present disclosure provides a display device including the thin film transistor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plane view of a thin film transistor according to one embodiment of the present disclosure.

FIG. 2 is a cross-sectional view taken along line I-I′ of FIG. 1 according to one embodiment of the present disclosure.

FIG. 3 is a cross-sectional view taken along line II-II′ of FIG. 1 according to one embodiment of the present disclosure.

FIG. 4 is a plane view of a thin film transistor according to another embodiment of the present disclosure.

FIG. 5 is a plane view of a thin film transistor according to another embodiment of the present disclosure.

FIG. 6 is a plane view of a thin film transistor according to another embodiment of the present disclosure.

FIG. 7 is a plane view of a thin film transistor according to another embodiment of the present disclosure.

FIGS. 8A to 8D are process plane views showing a manufacturing process of a thin film transistor according to one embodiment of the present disclosure.

FIGS. 9A to 9D are a cross-sectional view taken along line III-III of FIGS. 8A to 8D according to one embodiment of the present disclosure.

FIGS. 10A to 10D are a cross-sectional view taken along line IV-IV of FIGS. 8A to 8D according to one embodiment of the present disclosure.

FIG. 11 is a schematic diagram of a display device according to one embodiment of the present disclosure.

FIG. 12 is a schematic diagram of a shift register according to one embodiment of the present disclosure.

FIG. 13 is a circuit diagram of a stage provided in the shift register of FIG. 12 according to one embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

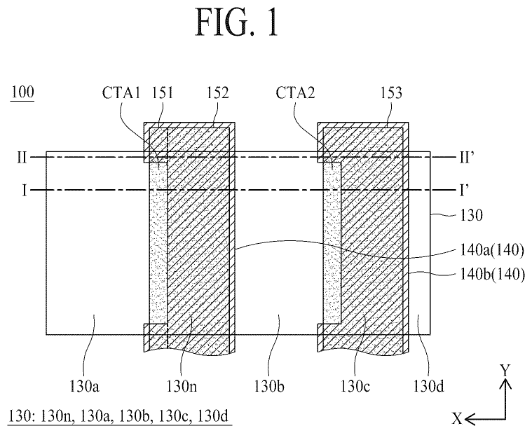

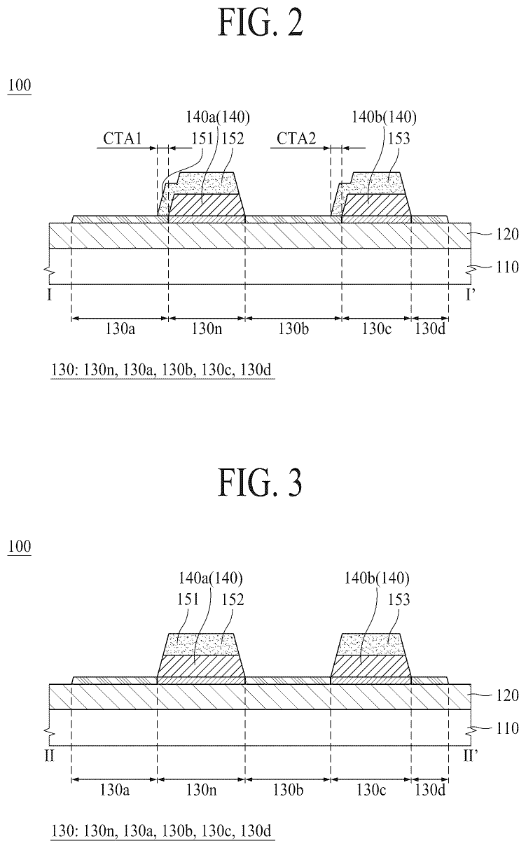

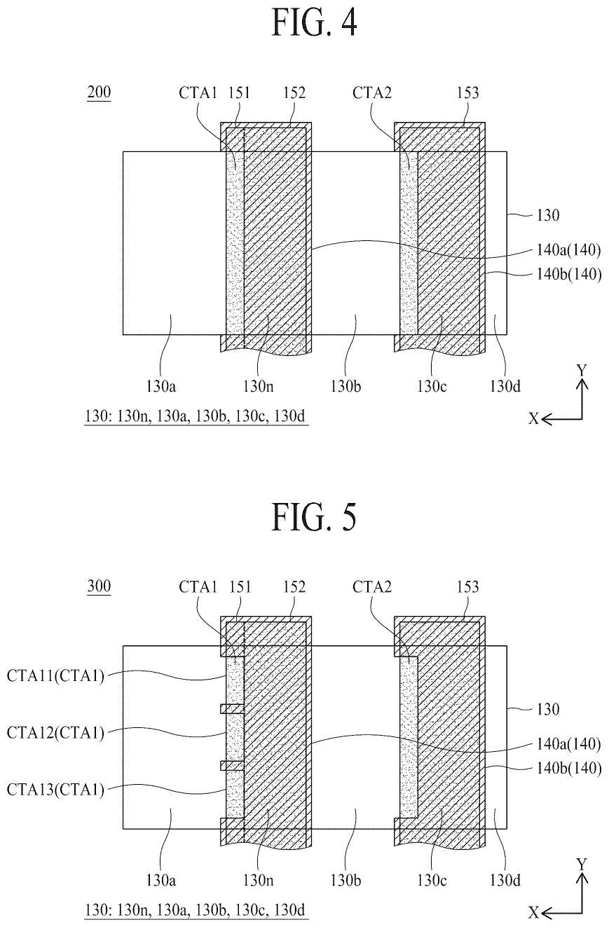

FIG. 1 is a plane view of a thin film transistor (100) according to one embodiment of the present disclosure. FIG. 2 is a cross-sectional view taken along line I-I′ of FIG. 1 according to one embodiment of the present disclosure. FIG. 3 is a cross-sectional view taken along line II-II′ of FIG. 1 according to one embodiment of the present disclosure.

Referring to FIGS. 1, 2, and 3, a thin film transistor (100) according to one embodiment of the present disclosure may include an active layer (130), a gate insulating film (140), a drain electrode (151), a gate electrode (152), and a source electrode (153).

Specifically, referring to FIGS. 1 to 3, a thin film transistor (100) according to one embodiment of the present disclosure may include a base substrate (110), a buffer layer (120) on the base substrate (110), an active layer (130) on the buffer layer (120), a gate insulating film (140) on the active layer (130), a drain electrode (151), a gate electrode (152), and a source electrode (153) on the gate insulating film (140).

Below, components of a thin film transistor (100) according to one embodiment of the present disclosure are described in detail.

The base substrate (110) may be made of glass or plastic. A transparent plastic having flexible properties, such as polyimide, may be used.

When polyimide is used as the base substrate (110), considering that a high-temperature deposition process is performed on the base substrate (110), a heat-resistant polyimide that can withstand high temperatures can be used. In this case, for forming a thin film transistor, processes such as deposition and etching can be performed while the polyimide substrate is disposed on a carrier substrate made of a highly durable material such as glass.

Although not shown in the drawing, a light-blocking layer (not shown) may be disposed on the base substrate (110).

A light-blocking layer (not shown) may be disposed between the base substrate (110) and the buffer layer (120). The light blocking layer (not shown) can overlap with the active layer (130). Specifically, the light blocking layer (not shown) may overlap the channel portion (130n). The light blocking layer (not shown) may block light incident from the outside, thereby protecting the channel portion (130n).

Light blocking layer (not shown) can be made of a material having light-blocking properties. The light blocking layer (not shown) may include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), and iron (Fe). According to an embodiment of the present invention, the light blocking layer (not shown) may have electrical conductivity.

Referring to FIGS. 2 and 3, a buffer layer (120) may be disposed on a base substrate (110).

The buffer layer (120) is formed on the base substrate (110) and may be formed of an inorganic material or an organic material. For example, it may include an insulating oxide such as silicon oxide (SiOx) or aluminum oxide (Al2O3).

The buffer layer (120) protects the active layer (130) by blocking impurities such as moisture and oxygen flowing in from the base substrate (110) and serves to flatten the upper portion of the base substrate (110). The buffer layer (120) can be formed as a single layer or multiple layers.

When the buffer layer (120) has multiple layers, each of the multiple layers can be formed of different materials.

Referring to FIGS. 2 and 3, an active layer (130) may be disposed on a buffer layer (120).

The active layer (130) may include a channel portion (130n), a first conductor portion (130a), a second conductor portion (130b), a semiconductor portion (130c), and a third conductor portion (130d).

Specifically, the channel portion (130n) may overlap with the gate electrode (152). Specifically, at least a portion of the channel portion (130n) may overlap with the gate electrode (152) in a plane. For example, the channel portion (130n) may not be in contact with the gate electrode (152).

The first conductor portion (130a) is disposed on one side of the channel portion (130n). For example, the first conductor portion (130a) may not overlap with the gate electrode (152), and at least a portion of the first conductor portion (130a) may overlap with the drain electrode (151). For example, at least a portion of the first conductor portion (130a) may be in contact with the drain electrode (151).

The second conductor portion (130b) is disposed on the other side of the channel portion (130n). In addition, the second conductor portion (130b) may be disposed on one side of the semiconductor portion (130c). For example, the second conductor portion (130b) may not overlap the gate electrode (152), and at least a portion of the second conductor portion (130b) may overlap the source electrode (153). For example, at least a portion of the second conductor portion (130b) may be in contact with the source electrode (153). The channel portion (130n) may be disposed between the first conductor portion (130a) and the second conductor portion (130b).

The semiconductor portion (130c) may overlap with the source electrode (153). Specifically, at least a portion of the semiconductor portion (130c) may overlap with the source electrode (153) in a plane. For example, the semiconductor portion (130c) may not be in contact with the source electrode (153). The second conductor portion (130b) may be disposed between the channel portion (130n) and the semiconductor portion (130c).

The third conductor portion (130d) is disposed on the other side of the semiconductor portion (130c). For example, the third conductor portion (130d) may not overlap with the source electrode (153). For example, at least a portion of the third conductor portion (130d) may not be in contact with the source electrode (153). The semiconductor portion (130c) may be disposed between the second conductor portion (130b) and the third conductor portion (130d).

According to one embodiment of the present disclosure, when the direction connecting the source electrode (153) and the drain electrode (151) in a plane with the shortest distance is referred to as the first direction (X), the direction perpendicular to the first direction (X) may be referred to as the second direction (Y).

According to one embodiment of the present disclosure, the first conductor portion (130a), the channel portion (130n), the second conductor portion (130b), the semiconductor portion (130c), and the third conductor portion (130d) can be disposed in parallel along the first direction.

According to one embodiment of the present disclosure, the active layer (130) may be formed of a semiconductor material. The active layer (130) may include an oxide semiconductor material.

The oxide semiconductor material may include, for example, at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, one embodiment of the present invention is not limited thereto, and the active layer (130) may be made of other oxide semiconductor materials known in the art.

The first conductive portion (130a), the second conductive portion (130b), and the third conductive portion (130d) can be formed by selective conductorization of an active layer (130) made of a semiconductor material. According to one embodiment of the present disclosure, selective conductorization refers to imparting conductivity to a specific portion of the active layer (130) so that it can function as a conductor.

For example, after the gate insulating film (140) is etched using a dry etching process, the exposed active layer (130) can be selectively conductorized using plasma. As a result, a first conductive portion (130a), a second conductive portion (130b), and a third conductive portion (130d) can be formed. However, one embodiment of the present disclosure is not limited thereto, and the active layer (130) can also be selectively conductorized by other methods known in the art.

The first conductive portion (130a), the second conductive portion (130b), and the third conductive portion (130d) do not overlap (e.g., non-overlapping) with the gate electrode (152). The first conductive portion (130a), the second conductive portion (130b), and the third conductive portion (130d) have superior electrical conductivity and high mobility compared to the channel portion (130n).

According to one embodiment of the present disclosure, the active layer (130) may have a multilayer structure. For example, although not shown in the drawing, the active layer (130) may include a first active layer and a second active layer.

The first active layer and the second active layer may include the same semiconductor material or may include different semiconductor materials.

According to one embodiment of the present disclosure, the thin film transistor (100) may further include a gate insulating film (140) between the active layer (130) and the gate electrode (152). Specifically, the gate insulating film (140) may be formed by patterning.

According to one embodiment of the present disclosure, the gate insulating film (140) may include a first gate insulating film (140a) and a second gate insulating film (140b). The first gate insulating film (140a) and the second gate insulating film (140b) may be disposed spaced apart from each other.

Referring to FIGS. 1 to 3, the first gate insulating film (140a) may overlap the gate electrode (152), and the second gate insulating film (140b) may overlap the source electrode (153). In addition, the first gate insulating film (140a) and the second gate insulating film (140b) may be disposed on the same layer. For example, referring to FIG. 2, the first gate insulating film (140a) and the second gate insulating film (140b) may each be disposed on the active layer (130).

The gate insulating film (140) may include at least one of silicon oxide, silicon nitride, and metal oxide. The gate insulating film (140) may have a single film structure or a multilayer film structure. The first gate insulating film (140a) protects the channel portion (130n).

Referring to FIGS. 1 to 3, the gate electrode (152) is disposed on the first gate insulating film (140a). The gate electrode (152) overlaps the channel portion (130n) of the active layer (130).

The gate electrode (152) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode (152) may also have a multilayer film structure including at least two conductive films having different physical properties.

Referring to FIGS. 1 to 3, the drain electrode (151) and the source electrode (153) may be respectively connected to the active layer (130) and disposed spaced apart from each other.

The drain electrode (151) and the source electrode (153) may each include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The drain electrode (151) and the source electrode (153) may each have a multilayer film structure including at least two conductive films having different physical properties.

According to one embodiment of the present disclosure, at least a portion of the drain electrode (151) and at least a portion of the source electrode (153) may not overlap with the gate insulating film (140). FIGS. 1 to 3 illustrate a portion of the drain electrode (151) and a portion of the source electrode (153) not overlapping with the gate insulating film (140).

For example, the drain electrode (151) may be in contact with the first conductive portion (130a) of the active layer (130), and the source electrode (153) may be in contact with the second conductive portion (130b) of the active layer (130). For example, the gate insulating film (140) may not be disposed between a part of the drain electrode (151) and the active layer (130), and the gate insulating film (140) may not be disposed between a part of the source electrode (153) and the active layer (130). For example, at least a part of the first conductive portion (130a) may be in contact with the drain electrode (151), and at least a part of the second conductive portion (130b) may be in contact with the source electrode (153).

Although not shown in the drawing, an interlayer insulating film (not shown) may be disposed on the drain electrode (151), the gate electrode (152), and the source electrode (153). The interlayer insulating film (not shown) is an insulating layer made of an insulating material. The interlayer insulating film (not shown) may be made of an organic material, an inorganic material, or a laminate of an organic layer and an inorganic layer.

According to one embodiment of the present disclosure, the drain electrode (151) and the gate electrode (152) may be formed integrally. Specifically, the drain electrode (151) and the gate electrode (152) may be formed of the same material by the same process.

In a diode thin film transistor, the gate electrode and the drain electrode can be connected. At this time, the gate electrode and the drain electrode can generally be connected through a contact hole or through external wiring.

However, if the gate electrode and drain electrode are connected through a contact hole or through external wiring, a problem may arise in which the area of the diode thin film transistor is not sufficiently reduced.

According to the present disclosure, the area of the thin film transistor (100) can be sufficiently reduced by forming the drain electrode (151) and the gate electrode (152) integrally.

According to one embodiment of the present disclosure, the drain electrode (151) and the gate electrode (152) may be formed integrally within a region overlapping the active layer (130) in a plane. Specifically, the drain electrode (151) and the gate electrode (152) may be formed integrally within a region occupied by the active layer (130) in a plane.

For example, if the drain electrode and the gate electrode are connected outside the area occupied by the active layer in a plane, the area occupied by the thin film transistor may not be sufficiently reduced.

Therefore, according to the present disclosure, in order to sufficiently reduce the area of the region occupied by the thin film transistor (100), the drain electrode (151) and the gate electrode (152) may be formed integrally within a region overlapping the active layer (130) in a plane. For example, the drain electrode (151) may mean a region that does not overlap (e.g., non-overlapping) with the first gate insulating film (140a) and may mean a region overlapping with the first conductor portion (130a). For example, the gate electrode (152) may mean a region overlapping with the first gate insulating film (140a) and may mean a region overlapping with the channel portion (130n).

According to one embodiment of the present disclosure, the drain electrode (151), the gate electrode (152), and the source electrode (153) may be disposed on the same layer. For example, the drain electrode (151), the gate electrode (152), and the source electrode (153) may each be disposed on the gate insulating film (140). Specifically, the drain electrode (151), the gate electrode (152), and the source electrode (153) may be formed by the same process using the same material.

According to one embodiment of the present disclosure, the drain electrode (151) may be in contact with the active layer (130) along the side surface of the first gate insulating film (140a). For example, referring to FIG. 2, the drain electrode (151) may be in contact with the first conductor portion (130a) of the active layer (130) along the side surface of the first gate insulating film (140a).

Since the drain electrode (151) is in contact with the active layer (130) along the side of the first gate insulating film (140a), the drain electrode (151) can be in contact with the active layer (130) stably.

According to one embodiment of the present invention, the source electrode (153) may be in contact with the active layer (130) along the side surface of the second gate insulating film (140b). For example, referring to FIG. 2, the source electrode (153) may be in contact with the second conductive portion (130b) of the active layer (130) along the side surface of the second gate insulating film (140b).

Since the source electrode (153) is in contact with the active layer (130) along the side of the second gate insulating film (140b), the source electrode (153) can be in contact with the active layer (130) stably.

According to one embodiment of the present invention, the drain electrode (151) can contact the active layer (130) at the first contact area (CTA1). Additionally, the source electrode (153) can contact the active layer (130) at the second contact area (CTA2).

For example, referring to FIGS. 1 and 2, the drain electrode (151) may contact the first conductive portion (130a) of the active layer (130) in the first contact area (CTA1), and the source electrode (153) may contact the second conductive portion (130b) of the active layer (130) in the second contact area (CTA2).

Referring to FIGS. 1 to 3, the first contact area (CTA1) and the second contact area (CTA2) may be disposed to extend along the second direction (Y), respectively. FIGS. 1 to 3 illustrate that the first contact area (CTA1) and the second contact area (CTA2) are disposed spaced apart from the ends of the active layer (130), but the present disclosure is not limited thereto, and the first contact area (CTA1) and the second contact area (CTA2) may also meet the ends of the active layer (130), respectively.

According to one embodiment of the present disclosure, the first contact area (CTA1) and the second contact area (CTA2) can be disposed side by side and spaced apart from each other along the first direction (X).

According to one embodiment of the present disclosure, the first contact area (CTA1) may overlap the first conductor portion (130a) in a plane, and the second contact area (CTA2) may overlap the second conductor portion (130b).

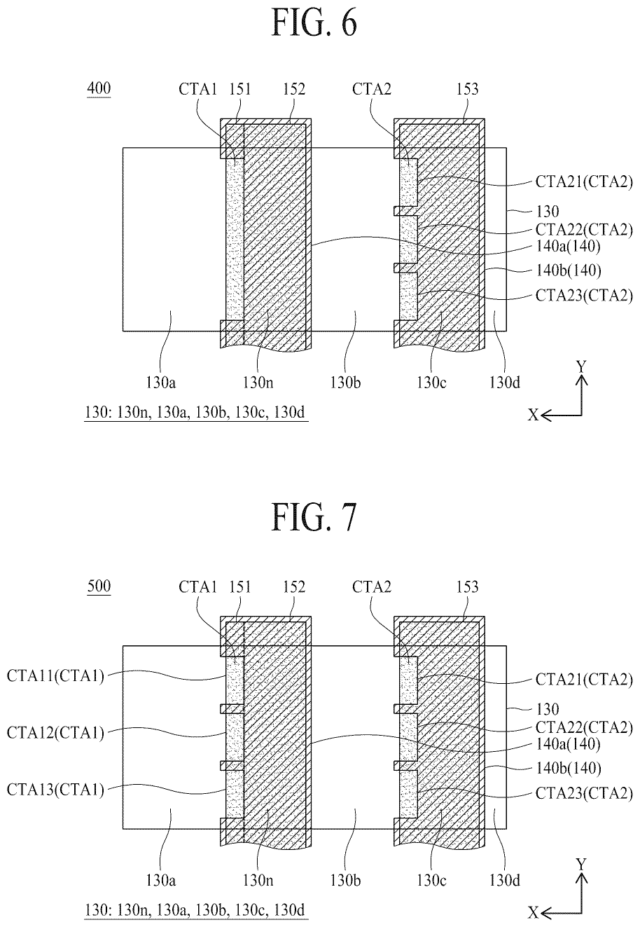

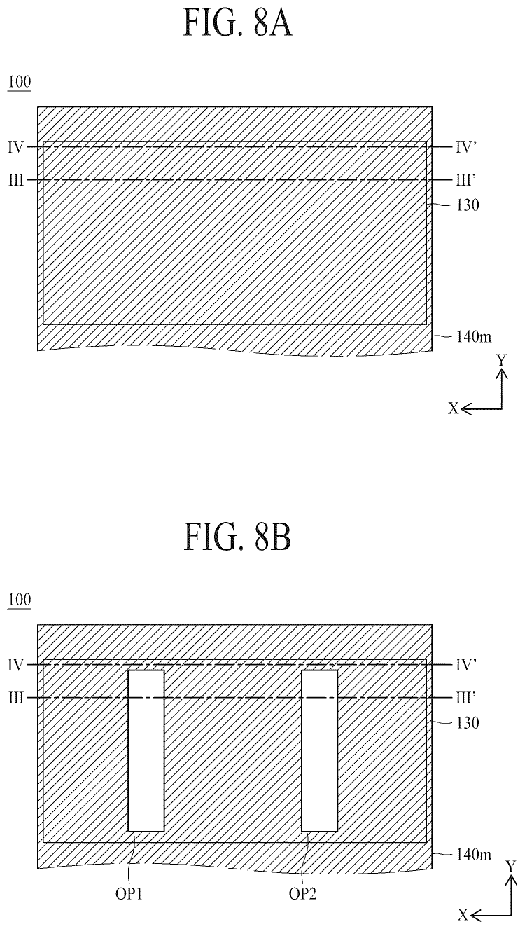

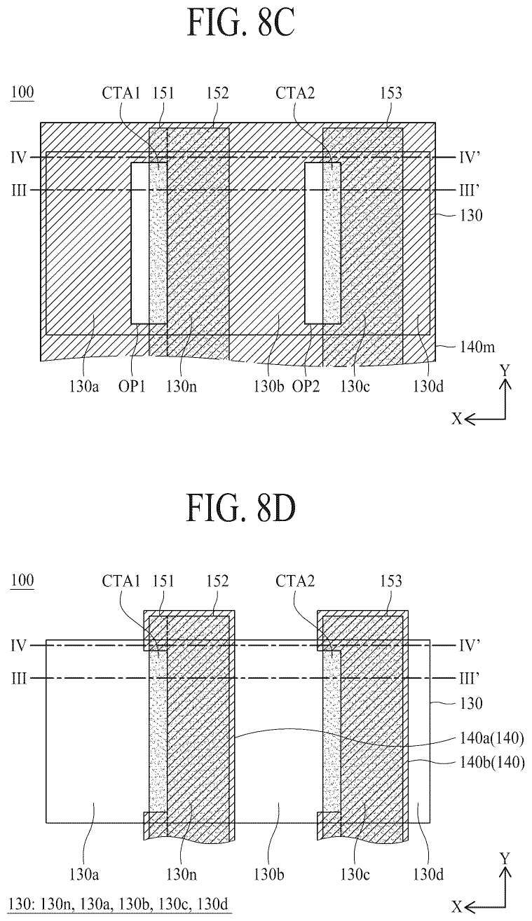

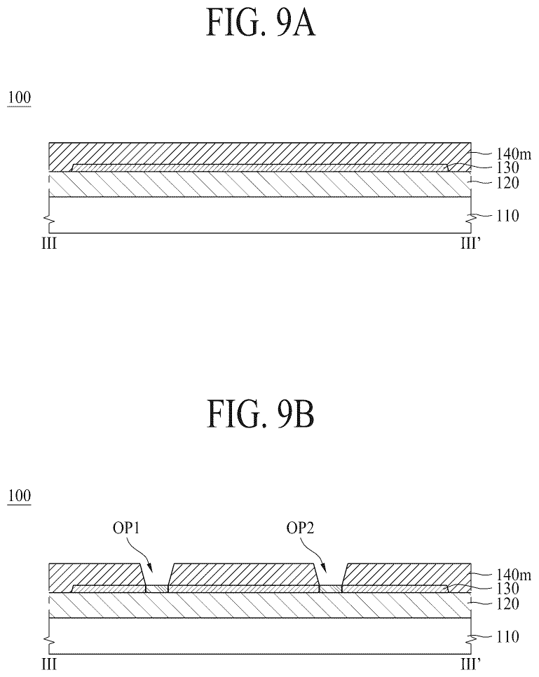

FIG. 4 is a plane view of a thin film transistor (200) according to another embodiment of the present disclosure. FIG. 5 is a plane view of a thin film transistor (300) according to another embodiment of the present disclosure. FIG. 6 is a plane view of a thin film transistor (400) according to another embodiment of the present disclosure. FIG. 7 is a plane view of a thin film transistor (500) according to another embodiment of the present disclosure.

According to one embodiment of the present disclosure, the first contact area (CTA1) and the second contact area (CTA2) in a plane view may be disposed to be spaced apart from the end of the active layer (130) in the second direction (Y) (see FIGS. 1 to 3). However, the present disclosure is not limited thereto, and at least one of the first contact area (CTA1) and the second contact area (CTA2) in a plane view may overlap the end of the active layer (130) in the second direction (Y). For example, FIG. 4 illustrates a configuration in which the first contact area (CTA1) and the second contact area (CTA2) in a plane view overlap the end of the active layer (130) in the second direction (Y).

Compared to the thin film transistor (200) illustrated in FIG. 4, according to the thin film transistor (100) illustrated in FIGS. 1 to 3, the first contact area (CTA1) and the second contact area (CTA2) are disposed to be spaced apart from the end of the active layer (130) with respect to the second direction (Y), so that the width length of the boundary between the first conductive portion (130a) and the channel portion (130n) with respect to the second direction (Y) can be shortened. As a result, the conductorization diffusion from the first conductive portion (130a) to the channel portion (130n) can be suppressed. As a result, the threshold voltage (Vth) of the thin film transistor (100) can be prevented or suppressed from shifting in the negative (−) direction.

According to one embodiment of the present disclosure, the first contact area (CTA1) may include a plurality of first sub-contact areas (CTA11, CTA12, CTA13) spaced apart from each other.

FIG. 5 illustrates a first contact area (CTA1) including a plurality of first sub-contact areas (CTA11, CTA12, CTA13) spaced apart from each other. The present disclosure is not limited thereto, and the first contact area (CTA1) may include less than three first sub-contact areas or may include four or more first sub-contact areas.

FIG. 5 illustrates a 1-1 sub-contact area (CTA11), a 1-2 sub-contact area (CTA12), and a 1-3 sub-contact area (CTA13) disposed in a parallel manner along the second direction (Y).

According to one embodiment of the present disclosure, the drain electrode (151) may be in contact with the first conductor portion (130a) of the active layer (130) in the plurality of first sub-contact areas (CTA11, CTA12, CTA13). For example, the plurality of first sub-contact areas (CTA11, CTA12, CTA13) may not overlap with the gate insulating film (140). For example, the gate insulating film (140) may be disposed between the plurality of first sub-contact areas (CTA11, CTA12, CTA13). Specifically, the first gate insulating film (140a) may be disposed between the plurality of first sub-contact areas (CTA11, CTA12, CTA13).

Generally, if the channel portion (130n) has a large width, when the conductorization diffusion proceeds with respect to the first conductive portion (130a), the width of the boundary between the channel portion (130n) and the first conductive portion (130a) with respect to the second direction (Y) becomes longer, and thus the conductorization diffusion toward the channel portion (130n) may proceed significantly. When the conductorization diffusion toward the channel portion (130n) proceeds significantly, the threshold voltage (Vth) of the thin film transistor (100) may move in the negative (−) direction, and thus the operating stability of the thin film transistor (100) may deteriorate.

On the other hand, if the channel portion (130n) has a small width, when the conductorization diffusion proceeds with respect to the first conductive portion (130a), the width of the boundary between the channel portion (130n) and the first conductive portion (130a) in the second direction (Y) becomes shorter, so that the conductorization diffusion toward the channel portion (130n) can be suppressed.

According to the present disclosure, when the drain electrode (151) is in contact with the first conductive portion (130a) of the active layer (130) in the plurality of first sub-contact areas (CTA11, CTA12, CTA13), the width length of the boundary between the first conductive portion (130a) and the channel portion (130n) with respect to the second direction (Y) can be shortened by the width length of the plurality of first sub-contact areas (CTA11, CTA12, CTA13). As a result, the conductorization diffusion from the first conductive portion (130a) to the channel portion (130n) can be suppressed. As a result, the threshold voltage (Vth) of the thin film transistor (100) can be prevented or suppressed from shifting in the negative (−) direction.

According to one embodiment of the present disclosure, the second contact area (CTA2) may include a plurality of second sub-contact areas (CTA21, CTA22, CTA23) spaced apart from each other.

FIG. 6 illustrates a second contact area (CTA2) including a plurality of second sub-contact areas (CTA21, CTA22, CTA23) spaced apart from each other. The present disclosure is not limited thereto, and the second contact area (CTA2) may include less than three plurality of second sub-contact areas, or may include four or more plurality of second sub-contact areas.

FIG. 6 illustrates a 1-2 sub-contact area (CTA21), a 2-2 sub-contact area (CTA22), and a 2-3 sub-contact area (CTA23) disposed in parallel along the second direction (Y).

According to one embodiment of the present disclosure, the source electrode (153) may be in contact with the second conductor portion (130b) of the active layer (130) in the plurality of second sub-contact areas (CTA21, CTA22, CTA23). For example, the plurality of second sub-contact areas (CTA21, CTA22, CTA23) may not overlap with the gate insulating film (140). For example, the gate insulating film (140) may be disposed between the plurality of second sub-contact areas (CTA21, CTA22, CTA23). Specifically, the second gate insulating film (140b) may be disposed between the plurality of second sub-contact areas (CTA21, CTA22, CTA23).

According to the present disclosure, when the source electrode (153) is in contact with the second conductor portion (130b) of the active layer (130) in a plurality of second sub-contact areas (CTA21, CTA22, CTA23), the contact resistance can be reduced.

Compared to the thin film transistor (300) illustrated in FIG. 5, the thin film transistor (500) illustrated in FIG. 7 may include a second contact area (CTA2) that includes a plurality of second sub-contact areas (CTA21, CTA22, CTA23) spaced apart from each other.

Compared to the thin film transistor (400) illustrated in FIG. 6, the thin film transistor (500) illustrated in FIG. 7 may include a first contact area (CTA1) that includes a plurality of first sub-contact areas (CTA11, CTA12, CTA13) spaced apart from each other.

Referring to FIG. 7, the first contact area (CTA1) may include a plurality of first sub-contact areas (CTA11, CTA12, CTA13) spaced apart from each other, and the second contact area (CTA2) may include a plurality of second sub-contact areas (CTA21, CTA22, CTA23) spaced apart from each other.

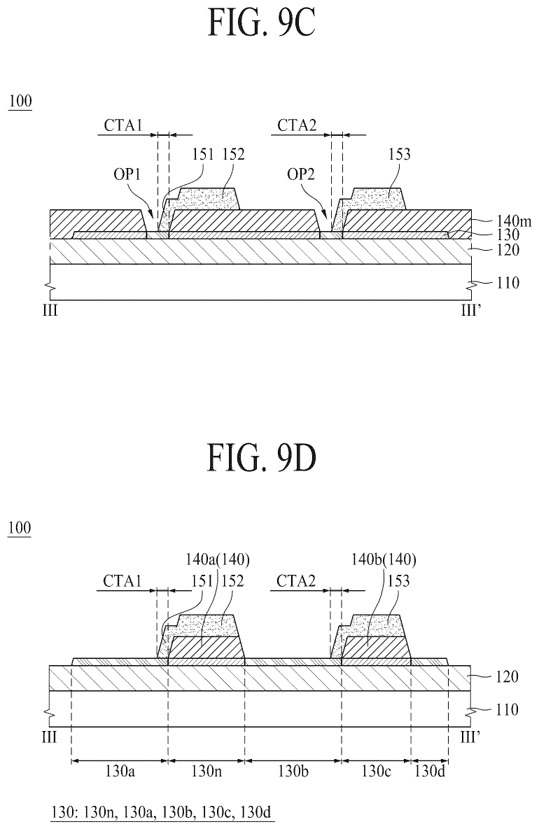

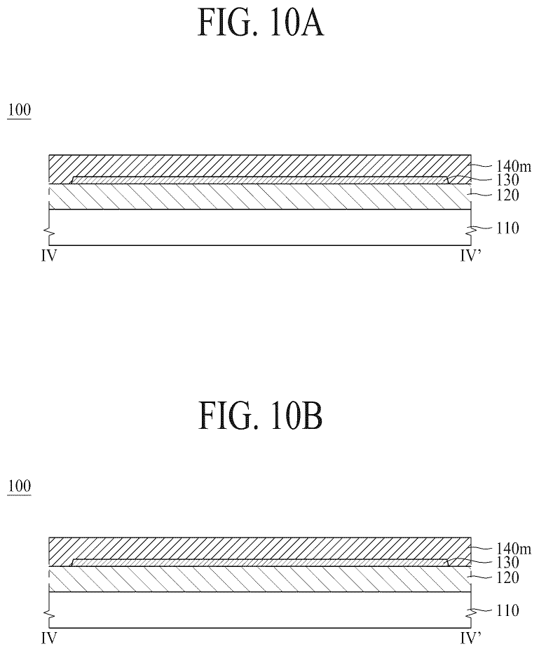

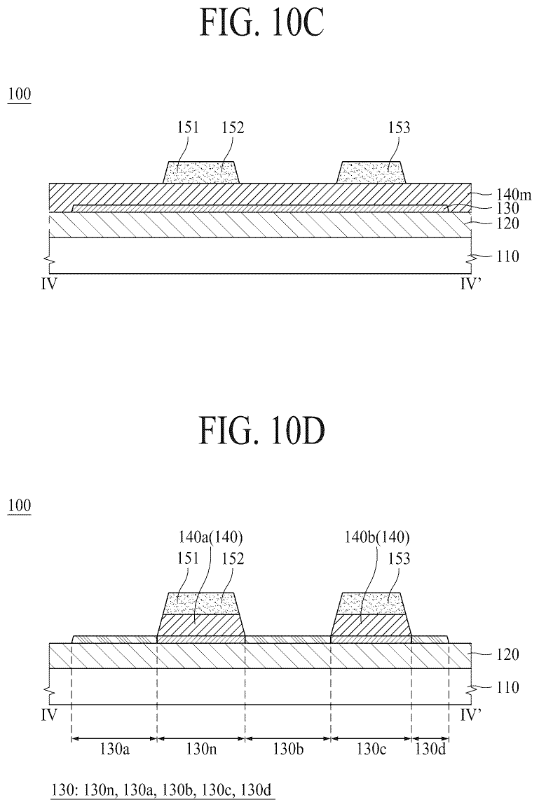

FIGS. 8A to 8D are plane views showing a manufacturing process of a thin film transistor according to one embodiment of the present disclosure. FIGS. 9A to 9D are cross-sectional views taken along line III-III′ of FIGS. 8A to 8D according to one embodiment of the present disclosure. FIGS. 10A to 10D are cross-sectional views taken along line IV-IV′ of FIGS. 8A to 8D according to one embodiment of the present disclosure.

The plane views of FIGS. 8A to 8D correspond to the plane views of the thin film transistor (100) illustrated in FIG. 1, the cross-sectional views taken along line III-III′ of FIGS. 9A to 9D correspond to the cross-sectional views of the thin film transistor (100) illustrated in FIG. 2, and the cross-sectional views taken along line IV-IV′ of FIGS. 10A to 10D correspond to the cross-sectional views of the thin film transistor (100) illustrated in FIG. 3.

Referring to FIG. 8A, FIG. 9A, and FIG. 10A, a buffer layer (120) is formed on a base substrate (110), an active layer (130) is formed on the buffer layer (120), and a gate insulating material layer (140m) is formed on the active layer (130).

The gate insulating material layer (140m) may include at least one of silicon oxide, silicon nitride, and metal oxide.

Referring to FIGS. 8B, 9B, and 10B, a gate insulating material layer (140m) may be etched to form a first open area (OP1) and a second open area (OP2). The first open area (OP1) and the second open area (OP2) may overlap the active layer (130) in a plane. The open area may be surrounded by the gate insulating material layer (140m).

Referring to FIG. 9B, a portion of the exposed active layer (130) can be selectively conductorized by etching the gate insulating material layer (140m) using dry etching.

The area covered by the gate insulating material layer (140m) among the active layers (130) is not conductorized and may be a semiconductor area.

Referring to FIG. 8C, FIG. 9C, and FIG. 10C, a drain electrode (151), a gate electrode (152), and a source electrode (153) can be formed on a gate insulating material layer (140m). The drain electrode (151) and the gate electrode (152) can be formed integrally.

The drain electrode (151) can contact the active layer (130) within the first open area (OP1), and the source electrode (153) can contact the active layer (130) within the second open area (OP2).

Referring to FIG. 8C, FIG. 9C, and FIG. 10C, the drain electrode (151) may not be disposed in the entire area of the first open area (OP1), but may be disposed in a partial area of the first open area (OP1), and the source electrode (153) may not be disposed in the entire area of the second open area (OP2), but may be disposed in a partial area of the second open area (OP2).

Descriptions of the configurations described above among the configurations illustrated in FIGS. 8C, 9C, and 10C are omitted.

Referring to FIG. 8D, FIG. 9D, and FIG. 10D, a gate insulating film (140) can be formed by etching a gate insulating material layer (140m) using a drain electrode (151), a gate electrode (152), and a source electrode (153) as a mask.

Referring to FIGS. 9D and 10D, a portion of the exposed active layer (130) can be selectively conductorized by etching the gate insulating material layer (140m) using dry etching as a mask for the drain electrode (151), the gate electrode (152), and the source electrode (153).

The area covered by the gate insulating film (140) among the active layer (130) is not conductorized and may be a semiconductor area.

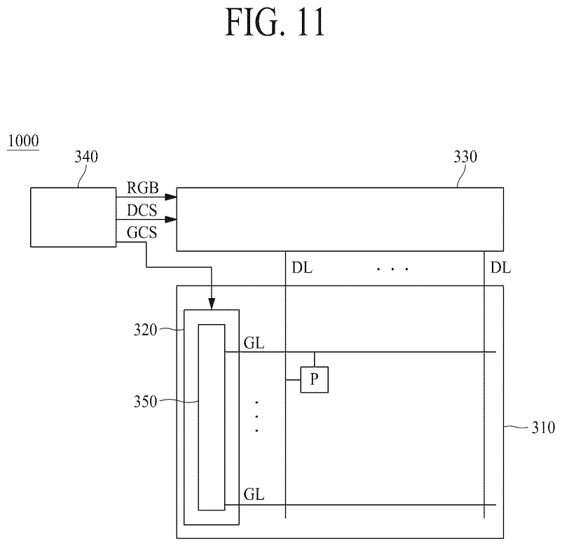

FIG. 11 is a schematic diagram of a display device (1000) according to another embodiment of the present disclosure.

A display device (1000) according to another embodiment of the present invention may include a display panel (310), a gate driver (320), a data driver (330), and a control unit (340), as illustrated in FIG. 11.

The display panel (310) includes gate lines (GL) and data lines (DL), and pixels (P) are disposed at intersections of the gate lines (GL) and data lines (DL). An image is displayed by driving the pixels (P). The gate lines (GL), data lines (DL), and pixels (P) may be disposed on a base substrate (110).

The control unit (340) is, for example, a circuit that controls the gate driver (320) and the data driver (330).

The control unit (340) outputs a gate control signal (GCS) for controlling the gate driver (320) and a data control signal (DCS) for controlling the data driver (330) using a signal supplied from an external system (not shown). In addition, the control unit (340) samples input image data input from an external system, rearranges it, and supplies rearranged digital image data (RGB) to the data driver (330).

Gate Control signal (GCS) includes a gate start pulse (GSP), a gate shift clock (GSC), a gate output enable signal (GOE), a start signal (Vst), and a gate clock (GCLK). In addition, the gate control signal (GCS) may include control signals for controlling the shift register.

Data control signals (DCS) include source start pulse (SSP), source shift clock signal (SSC), source output enable signal (SOE), and polarity control signal (POL).

The data driver (330) supplies data voltage to the data lines (DL) of the display panel (310). Specifically, the data driver (330) converts image data (RGB) input from the control unit (340) into analog data voltage and supplies the data voltage to data lines (DL).

According to one embodiment of the present disclosure, the gate driver (320) may be mounted on the display panel (310). In this way, a structure in which the gate driver (320) is directly mounted on the display panel (310) is called a gate in panel (GIP) structure. Specifically, in the gate in panel (GIP) structure, the gate driver (320) may be disposed on the base substrate (110).

A display device (1000) according to one embodiment of the present disclosure may include the thin film transistor (100, 200, 300, 400) described above. According to one embodiment of the present disclosure, a gate driver (320) may include the thin film transistor (100, 200, 300, 400) described above.

The gate driver (320) may include a shift register (350).

Shift register (350) sequentially supplies gate pulses to gate lines (GL) for one frame using a start signal and gate clock transmitted from the control unit (340). Here, one frame refers to a period during which one image is output through the display panel (310). The gate pulse has a turn-on voltage capable of turning on a switching element (thin film transistor) disposed in a pixel (P).

In addition, the shift register (350) supplies a gate off signal capable of turning off the switching element to the gate line (GL) during the remaining period during which the gate pulse is not supplied during one frame. Hereinafter, the gate pulse and the gate off signal are collectively referred to as a scan signal (SS or Scan).

Shift The register (350) may include the thin film transistor (100, 200, 300, 400) described above.

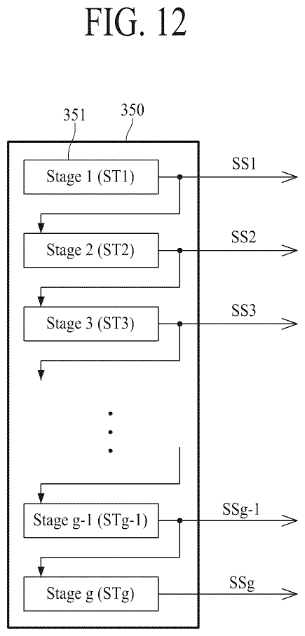

FIG. 12 is a schematic diagram of a shift register (350) according to one embodiment of the present disclosure.

Referring to FIG. 12, the shift register (350) may include g stages (351) (ST1 to STg).

The shift register (350) transmits one scan signal (SS) to pixels (P) connected to one gate line (GL) through one gate line (GL). Each of the stages (351) can be connected to one gate line (GL). When g gate lines (GL) are formed in the display panel (310), the shift register (350) can include g stages (351) (ST1 to STg) and generate g scan signals (SS1 to SSg).

In general, each stage (351) outputs a gate pulse (GP) once during one frame, and the gate pulses (GP) are sequentially output from each stage (351).

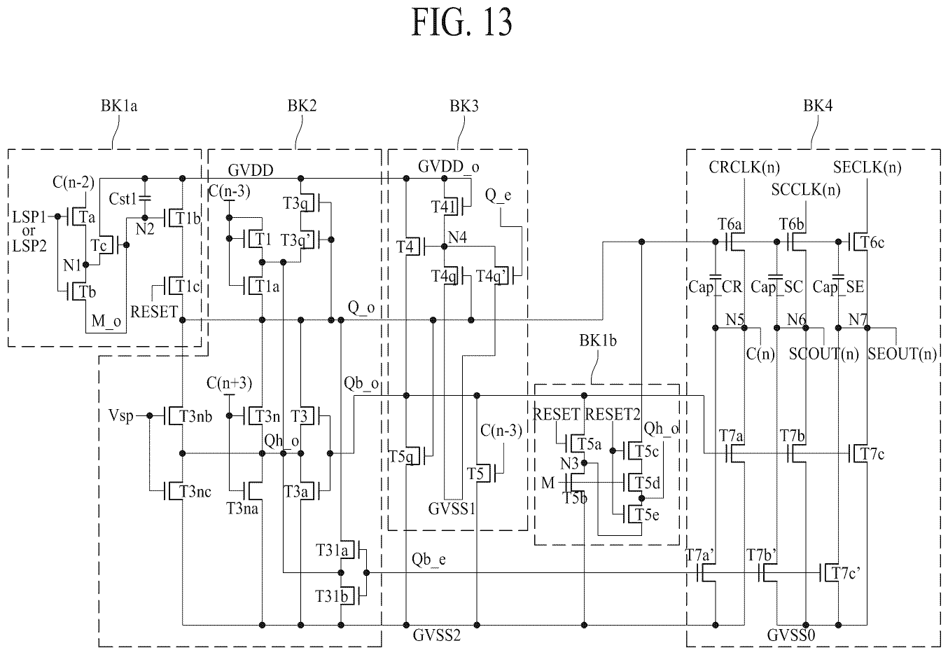

FIG. 13 is a circuit diagram of one embodiment of a stage (351) provided in the shift register (350) of FIG. 12 according to one embodiment of the present disclosure.

Referring to FIG. 13, a stage (ST) according to one embodiment of the present invention includes a M_o node, a Q_o node, a Q_e node, a Qb_o node, a Qb_e node, and a Qh_o node.

Referring to FIG. 13, the stage (ST) includes a first sensing control block (BK1a), a second sensing control block (BK1b), an input block (BK2), an inverter block (BK3), and an output block (BK4).

The first sensing control block (BK1a) applies a carry signal C(n−2) to the node M_o according to the line sampling signals (LSP1, LSP2) to activate the potential of the node M_o to the high-potential power supply voltage GVDD, and activates the potential of the node Q_o to the high-potential power supply voltage GVDD according to the activation potential of the node M_o and the global reset signal (RESET).

For this purpose, the first sensing control block (BK1a) includes a plurality of transistors (Ta, Tb, Tc, Tlb, Tlc) and a capacitor (Cst1).

Transistor Ta includes a gate electrode to which line sampling signals (LSP1, LSP2) are applied, a drain electrode to which a carry signal C(n−2) is applied, and a source electrode connected to node N1. Transistor Tb includes a gate electrode to which line sampling signals (LSP1, LSP2) are applied, a drain electrode connected to node N1, and a source electrode connected to node M_o. Transistor Tc includes a gate electrode connected to node N2, a drain electrode to which a high-potential power supply voltage GVDD is applied, and a source electrode connected to node N1. Transistor Tlb includes a gate electrode connected to node N2, a drain electrode to which a high-potential power supply voltage GVDD is applied, and a source electrode connected to the drain electrode of transistor Tlc. Capacitor Cst1 is connected between an input terminal of the high-potential power supply voltage GVDD and node N2 to maintain an activation potential of node M_o. Transistor Tlc includes a gate electrode to which a global reset signal (RESET) is applied, a drain electrode connected to the source electrode of transistor Tlb, and a source electrode connected to node Q_o.

The second sensing control block (BK1b) deactivates the potential of node Qb_o to the low potential power supply voltage GVSS2 according to the global reset signal (RESET) and the potential of node M.

To this end, the second sensing control block (BK1b) includes a plurality of transistors (T5a, T5b, T5c, T5d, T5e). The transistor T5a includes a gate electrode to which a global reset signal (RESET) is applied, a drain electrode connected to a node Qb_o, and a source electrode connected to a node N3. The transistor T5b includes a gate electrode connected to a node M, a drain electrode connected to a node N3, and a source electrode to which a low-potential power supply voltage GVSS2 is applied. The transistor T5c includes a gate electrode to which a second global reset signal (RESET2) is applied, a drain electrode connected to a node Q_o, and a source electrode connected to the drain electrode of the transistor T5d. The transistor T5d includes a gate electrode to which a second global reset signal (RESET2) is applied, a drain electrode connected to the source electrode of the transistor T5c, and a source electrode connected to the node Qh_o. Transistor T5e includes a gate electrode to which a second global reset signal (RESET2) is applied, a drain electrode connected to node Qh_o, and a source electrode connected to node N3.

The input block (BK2) applies a carry signal C(n−3) to the node Q_o to activate the potential of the node Qh_o to the high-potential power supply voltage GVDD. The second sensing control block (BK1b) deactivates the potential of the node Q_o to the low-potential power supply voltage GVSS2 according to the carry signal C(n+3). The second sensing control block (BK1b) deactivates the potential of the node Q_o to the low-potential power supply voltage GVSS2 according to the potential of the node Qb_o or Qb_e. The second sensing control block (BK1b) deactivates the potential of the node Q_o to the low-potential power supply voltage GVSS2 according to the global start pulse (Vsp).

For this purpose, the input block (BK2) includes a plurality of transistors (T1, T1a, T3q, T3q′, T3n, T3na, T3, T3a, T31a, T31b, T3nb, T3nc). The transistor T1 includes a gate electrode to which a carry signal C(n−3) is applied, a drain electrode, and a source electrode connected to a node Qh_o. The transistor T1a includes a gate electrode to which a carry signal C(n−3) is applied, a drain electrode connected to the node Qh_o, and a source electrode connected to the node Q_o. The transistor T3q includes a gate electrode connected to the node Q_o, a drain electrode to which a high-potential power supply voltage GVDD is applied, and a source electrode connected to the drain electrode of the transistor T3q′. The transistor T3q′ includes a gate electrode connected to the node Q_o, a drain electrode connected to the source electrode of the transistor T3q, and a source electrode connected to the node Qh_o. The transistor T3n includes a gate electrode to which a carry signal C(n+3) is applied, a drain electrode connected to a node Q_o, and a source electrode connected to a node Qh_o. The transistor T3na includes a gate electrode to which a carry signal C(n+3) is applied, a drain electrode connected to a node Qh_o, and a source electrode to which a low-potential power supply voltage GVSS2 is applied. The transistor T3 includes a gate electrode connected to a node Qb_o, a drain electrode connected to a node Q_o, and a source electrode connected to a node Qh_o. The transistor T3a includes a gate electrode connected to a node Qb_o, a drain electrode connected to a node Qh_o, and a source electrode to which a low-potential power supply voltage GVSS2 is applied. The transistor T31a includes a gate electrode connected to a node Qb_e, a drain electrode connected to a node Q_o, and a source electrode connected to a node Qh_o. The transistor T31b includes a gate electrode connected to a node Qb_e, a drain electrode connected to a node Qh_o, and a source electrode to which a low-potential power supply voltage GVSS2 is applied. The transistor T3nb includes a gate electrode to which a global start pulse (Vsp) is applied, a drain electrode connected to a node Q_o, and a source electrode connected to the node Qh_o. The transistor T3nc includes a gate electrode to which a global start pulse (Vsp) is applied, a drain electrode connected to a node Qh_o, and a source electrode connected to a low-potential power supply voltage GVSS2.

The inverter block (BK3) deactivates the potential of node Qb_o to the low-potential power voltage GVSS2 according to the carry signal C(n−3). The inverter block (BK3) deactivates the potential of node Qb_o to the low-potential power voltage GVSS2 according to the activation potential of node Q_o. The inverter block (BK3) applies the power voltage GVDD_o to the node N4 to activate the potential of node Qb_o to the power voltage GVDDo. The inverter block (BK3) deactivates the potential of the node N4 to the low-potential power voltage GVSS2 according to the activation potential of node Q_e.

For this purpose, the inverter block (BK3) includes a plurality of transistors (T4, T41, T4q, T4q′, T5, T5q). The transistor T4 includes a gate electrode connected to a node N4, a drain electrode to which a power supply voltage GVDD_o is applied, and a source electrode connected to a node Qb_o. The transistor T41 includes a gate electrode and a drain electrode to which a power supply voltage GVDD_o is applied, and a source electrode connected to the node N4. The transistor T4q includes a gate electrode connected to a node Q_o, a drain electrode connected to a node N4, and a source electrode connected to a low-potential power supply voltage GVSS1. The transistor T4q′ includes a gate electrode connected to a node Q_e, a drain electrode connected to a node N4, and a source electrode to which a low-potential power supply voltage GVSS1 is applied. Transistor T5 includes a gate electrode to which a carry signal C(n−3) is applied, a drain electrode connected to node Qb_o, and a source electrode to which a low-potential power supply voltage GVSS2 is applied. Transistor T5q includes a gate electrode connected to node Q_o, a drain electrode connected to node Qb_o, and a source electrode to which a low-potential power supply voltage GVSS2 is applied.

According to one embodiment of the present disclosure, the transistor T41 may include a thin film transistor (100, 200, 300, 400).

The output block (BK4) outputs a carry shift clock CRCLK (n) as a carry signal C(n) when the potential of the node Q_o is boosted from voltage level L2 to L3, and outputs a low-potential power supply voltage GVSS2 as a carry signal C(n) when the potential of the node Qb_o is activated to voltage level L2 or when the potential of the node Qb_e is activated to voltage level L2. The output block (BK4) outputs a scan shift clock SCCLK(n) as a gate pulse SCOUT (n) for image display when the potential of the node Q_o is boosted from level L2 to L3, and outputs a low-potential power supply voltage GVSS0 as a gate pulse SCOUT (n) for image display when the potential of the node Qb_o is activated to voltage level L2 or when the potential of the node Qb_e is activated to voltage level L2. The output block (BK4) outputs the sense shift clock SECLK(n) to the sense signal SEOUT(n) when the potential of node Q_o is boosted from level L2 to L3, and outputs the low-voltage power supply voltage GVSS0 to the sense signal SEOUT(n) when the potential of node Qb_o is activated to voltage level L2 or when the voltage of node Qb_e is activated to voltage level L2.

For this purpose, the output block (BK4) includes a plurality of pull-up transistors (T6a, T6b, T6c), a plurality of pull-down transistors (T7a, T7a′, T7b, T7b′, T7c, T7c′), and a plurality of capacitors (Cap_CR, Cap_SC, Cap_SE). The pull-up transistor T6a includes a gate electrode connected to the node Q_o, a drain electrode to which a carry shift clock CRCLK (n) is applied, and a source electrode connected to the node N5. The capacitor Cap_CR is connected between the node Q_o and the node N5. The pull-up transistor T6b includes a gate electrode connected to the node Q_o, a drain electrode to which a scan shift clock SCCLK(n) is applied, and a source electrode connected to the node N6. The capacitor Cap_SC is connected between the node Q_o and the node N6. The pull-up transistor T6c includes a gate electrode connected to the node Q_o, a drain electrode to which a sense shift clock SECLK(n) is applied, and a source electrode connected to the node N7. A capacitor Cap_SE is connected between the node Q_o and the node N7. The pull-down transistor T7a includes a gate electrode connected to the node Qb_o, a drain electrode connected to the node N5, and a source electrode connected to a low-potential power supply voltage GVSS2. The pull-down transistor T7a′ includes a gate electrode connected to the node Qb_e, a drain electrode connected to the node N5, and a source electrode connected to a low-potential power supply voltage GVSS2. The pull-down transistor T7b includes a gate electrode connected to the node Qb_o, a drain electrode connected to the node N6, and a source electrode connected to a low-potential power supply voltage GVSS0. The pull-down transistor T7b′ includes a gate electrode connected to the node Qb_e, a drain electrode connected to the node N6, and a source electrode connected to a low-potential power supply voltage GVSS0. The pull-down transistor T7c includes a gate electrode connected to the node Qb_o, a drain electrode connected to the node N7, and a source electrode connected to the low-potential power supply voltage GVSS0. The pull-down transistor T7c′ includes a gate electrode connected to the node Qb_e, a drain electrode connected to the node N7, and a source electrode connected to the low-potential power supply voltage GVSS0.

According to FIG. 13, the transistor T41 may include a thin film transistor (100, 200, 300, 400) according to the present disclosure. However, the present disclosure is not limited thereto.

According to the present disclosure, the following advantageous effects may be obtained.

A thin film transistor according to one embodiment of the present disclosure can minimize or at least reduce the area occupied by the thin film transistor by forming the drain electrode and the gate electrode integrally.

A thin film transistor according to another embodiment of the present disclosure can control the depth of penetration of the conductorization by configuring a plurality of areas where the drain electrode and the active layer come into contact.

In addition to the effects mentioned above, other features and advantages of the present disclosure are described below or may be clearly understood by those skilled in the art to which the present invention pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
an active layer;
a gate insulating film on the active layer;
a gate electrode at least partially overlapping the active layer; and
a source electrode and a drain electrode connected to the active layer, the source electrode and the drain electrode spaced apart from each other,
wherein the drain electrode and the gate electrode are formed integrally,
wherein the gate insulating film includes a first gate insulating film overlapping the gate electrode, and
wherein the drain electrode contacts the active layer along a side surface of the first gate insulating film.

2. The thin film transistor of claim 1, wherein the drain electrode and the gate electrode are formed integrally within a region overlapping the active layer in a plane.

3. The thin film transistor of claim 1, wherein the drain electrode, the gate electrode, and the source electrode are on a same layer.

4. The thin film transistor of claim 1, wherein the active layer includes:
a channel portion overlapping the gate electrode;
a first conductor portion on one side of the channel portion;
a second conductor portion on another side of the channel portion; and
a semiconductor portion overlapping the source electrode,
wherein the second conductor portion is between the channel portion and the semiconductor portion,
wherein at least a portion of the first conductor portion is in contact with the drain electrode,
wherein the gate insulating film further includes a second gate insulating film overlapping the source electrode,
wherein the source electrode is in contact with the active layer along a side surface of the second gate insulating film, and
wherein the first gate insulating film and the second gate insulating film are on a same layer and spaced apart from each other.

5. The thin film transistor of claim 4, wherein the drain electrode contacts the active layer in a first contact region and the source electrode contacts the active layer in a second contact region in a plane,
when a direction connecting the source electrode and the drain electrode with a shortest distance is referred to as a first direction, and a direction perpendicular to the first direction is referred to as a second direction, the first contact region and the second contact region extend along the second direction, respectively.

6. The thin film transistor of claim 5, wherein the first contact region and the second contact region are spaced apart from each other,
wherein the first contact region overlaps the first conductor portion and the second contact region overlaps the second conductor portion.

7. The thin film transistor of claim 5, wherein the first contact region and the second contact region are spaced apart from an end of the active layer with respect to the second direction in the plane.

8. The thin film transistor of claim 5, wherein at least one of the first contact region and the second contact region overlaps an end of the active layer in the second direction in the plane.

9. The thin film transistor of claim 5, wherein the first contact region includes a plurality of first sub-contact regions, and the plurality of first sub-contact regions are spaced apart from each other based on the second direction in the plane.

10. The thin film transistor of claim 9, wherein the first gate insulating film is between the plurality of first sub-contact regions in the plane.

11. The thin film transistor of claim 5, wherein the second contact region includes a plurality of second sub-contact regions spaced apart from each other, and the plurality of second sub-contact regions are spaced apart from each other based on the second direction in the plane.

12. The thin film transistor of claim 11, wherein the gate insulating film further includes a second gate insulating film overlapping the source electrode and the second gate insulating film is between the plurality of second sub-contact regions in the plane.

13. A manufacturing method of a thin film transistor comprising:
forming an active layer;
forming a gate insulating material layer on the active layer;
etching the gate insulating material layer to form a first open area and a second open area;
forming a drain electrode, a gate electrode, and a source electrode on the gate insulating material layer; and
etching the gate insulating material layer using the drain electrode, the gate electrode, and the source electrode as a mask to form a gate insulating film,
wherein the drain electrode is in contact with the active layer within the first open area,
wherein the source electrode is in contact with the active layer within the second open area, and
wherein the drain electrode and the gate electrode are formed integrally.

14. The manufacturing method of a thin film transistor of claim 13, wherein the gate insulating film includes a first gate insulating film overlapping the gate electrode and the drain electrode contacts the active layer along a side surface of the first gate insulating film.

15. The manufacturing method of a thin film transistor of claim 13, wherein the drain electrode and the gate electrode are formed integrally within a region overlapping the active layer in a plane.

16. The manufacturing method of a thin film transistor of claim 13, wherein the drain electrode, the gate electrode, and the source electrode are on a same layer.

17. The manufacturing method of a thin film transistor of claim 14, wherein the active layer includes:
a channel portion overlapping the gate electrode;
a first conductor portion on one side of the channel portion;
a second conductor portion on another side of the channel portion; and
a semiconductor portion overlapping the source electrode,
wherein the second conductor portion is between the channel portion and the semiconductor portion,
wherein at least a portion of the first conductor portion is in contact with the drain electrode,
wherein the gate insulating film further includes a second gate insulating film overlapping the source electrode,
wherein the source electrode is in contact with the active layer along a side surface of the second gate insulating film, and
wherein the first gate insulating film and the second gate insulating film are on a same layer and spaced apart from each other.

18. The manufacturing method of a thin film transistor of claim 17, wherein the drain electrode contacts the active layer in a first contact region and the source electrode contacts the active layer in a second contact region in a plane,
when a direction connecting the source electrode and the drain electrode with a shortest distance is referred to as a first direction and a direction perpendicular to the first direction is referred to as a second direction, the first contact region and the second contact region extend along the second direction, respectively.

19. The manufacturing method of a thin film transistor of claim 18, wherein the first contact region and the second contact region are spaced apart from each other,
wherein the first contact region overlaps the first conductor portion and the second contact region overlaps the second conductor portion.

20. A display apparatus comprising the thin film transistor of claim 1.
